(19) United States
(12) Patent Application Publication
(10) Pub. No.: US 2015/0316802 A1
(43) Pub. Date: Nov. 5, 2015

(54) SEMICONDUCTOR APPARATUS, DISPLAY PANEL, AND METHOD OF MANUFACTURING SEMICONDUCTOR APPARATUS

(71) Applicant: Sharp Kabushiki Kaisha, Osaka-shi, Osaka (JP)

(72) Inventors: Yudai TAKANISHI, Osaka-shi (JP); Yukinobu NAKATA, Osaka-shi (JP)

(21) Appl. No.: 14/423,490

(22) PCT Filed: Aug. 23, 2013
(86) PCT No.: PCT/JP2013/072588

§ 371 Date: Feb. 24, 2015

(30) Foreign Application Priority Data
Aug. 31, 2012 (JP) 2012-191594

(51) Int. Cl. G02F 1/1368; G02F 1/1333; G02F 1/1345; H01L 27/12; H01L 29/66; H01L 29/24; H01L 29/45; H01L 21/4757; H01L 21/475; G02F 1/1362; H01L 29/786

(52) U.S. Cl. CPC G02F 1/1368; G02F 1/136286; G02F 1/136227; G02F 1/133345; G02F 1/1345; H01L 27/124; H01L 29/7869; H01L 29/24; H01L 27/1225; H01L 29/45; H01L 27/1259; H01L 21/47573; H01L 21/475; H01L 29/66969

(57) ABSTRACT

The present invention prevents electric corrosion even when metal lines that may cause problems when in direct contact with ITO are used as source/drain lines, without increasing the number of steps for manufacturing a TFT substrate. A semiconductor apparatus includes TFTs that each include: a gate electrode included in a gate layer 11a provided on a substrate 20; a semiconductor element 15 provided above the gate layer 11a with a gate insulating film 21 positioned in between; and a source electrode and a drain electrode included in a source layer 12a located across the semiconductor element 15. The semiconductor apparatus includes, for a given TFT, a contact hole H1 formed in an interlayer insulating film 22 and planarizing film 23 stacked on the source layer 12a, and auxiliary line layer portions 13P and 13S made of a metal that can prevent electric corrosion between itself and ITO and located to overlap the associated source line, where a pixel electrode 17 is connected with the associated drain electrode 12D via the auxiliary line layer portion 13P. A common electrode 16 is provided to cover the auxiliary line layer portions 13S, and a potential is supplied to the common electrode 16 via the auxiliary line layer portions 13S.

### TECHNICAL FIELD

The present invention relates to a semiconductor apparatus using thin film transistors (TFTs), a display panel, and a method of manufacturing a semiconductor apparatus.

### BACKGROUND ART

In some conventional liquid crystal display devices using TFTs, an auxiliary capacitor Cs may be provided in a pixel and an auxiliary line may be provided for the auxiliary capacitor Cs. Particularly, in some fringe field switching (FFS) liquid crystal display devices, the auxiliary capacitor electrodes positioned in the pixels are spaced apart from the common electrode in order to stabilize the potential of the common electrode. However, particularly in display panels with high definition, which require high aperture ratios, it is difficult to fabricate an auxiliary capacitor or auxiliary line in a pixel. Thus, it is difficult to stabilize the potential of the common electrode by providing an auxiliary capacitor electrode in a pixel and connecting it with the common electrode.

JP 2010-231035 A discloses a liquid crystal display device including common electrode auxiliary lines CRM formed from a metal film. The use of common electrode auxiliary lines CRM reduces the overall electric resistance encountered when a voltage is applied to the common electrode, thereby stabilizing the potential of the common electrode. This eliminates the necessity to provide auxiliary capacitor electrodes or auxiliary lines in the pixels. Further, each common electrode auxiliary line overlies a gate signal line GL or drain signal line DL, improving the aperture ratio over a device with auxiliary capacitor lines or the like in the pixel regions.

### DISCLOSURE OF THE INVENTION

A TFT may include source/drain lines that are aluminum lines or metal lines mainly made of aluminum. When fabricating a TFT substrate having such aluminum-based metal lines as source/drain lines, forming a transparent conductive film of indium tin oxide (ITO), for example, by sputtering to form pixel electrodes or a common electrode may cause electric corrosion between the ITO and metal lines. This is also the case with a device of JP 2010-231035 A, where the source and drain signal lines are aluminum-based metal lines.

An object of the present invention is to provide a technique to prevent electric corrosion even when metal lines that may cause problems when in direct contact with ITO are used as source/drain lines, without increasing the number of steps for manufacturing a TFT substrate.

A semiconductor apparatus according to the present invention is a semiconductor apparatus including: a substrate; a plurality of gate lines located on the substrate; a gate insulating film covering the gate lines; a semiconductor layer having portions that overlie the gate lines, with the gate insulating film positioned in between; a plurality of source lines located on the gate insulating film and each covering portions of the semiconductor layer to cross the gate lines; a plurality of drain lines located on the gate insulating film and each covering a portion of the semiconductor layer so as to be spaced apart from one of the source lines across a portion of the semiconductor layer and overlie one of the gate lines; thin film transistors each including a channel region located over a portion of the semiconductor layer between a source line and a drain line; a drain connecting film made of a portion of a metal film for electrically connecting to a drain line via a first contact hole that extends through a first interlayer insulating film and a planarizing film, the first interlayer insulating film covering the source lines and drain lines and the channel regions, the planarizing film covering the first interlayer insulating film; common electrode auxiliary wiring made of a portion of the metal film, including a common electrode auxiliary line overlying at least one of the source lines and a common electrode auxiliary line provided for at least one of the gate lines so as to be located close to this gate line and extend generally parallel thereto; a common electrode overlying at least a part of the common electrode auxiliary line and electrically connected with the common electrode auxiliary line; and a pixel electrode electrically connected with the drain connecting film in a second contact hole, the second contact hole being formed in a second interlayer insulating film that contacts the drain connecting film and being located inside the first contact hole, wherein the metal film is constructed such that a metal having a higher standard electrode potential than the pixel electrode or a metal having a standard electrode potential that differs from that of the pixel electrode by an amount in a predetermined range is included so as to contact the pixel electrode, and the common electrode auxiliary line supplies the common electrode with a potential that depends on an input signal.

The semiconductor apparatus of the present invention prevents electric corrosion even when metal lines that may cause problems when in direct contact with ITO are used as source/drain lines, without increasing the number of steps for manufacturing a TFT substrate.

### BRIEF DESCRIPTION OF THE DRAWINGS

FIG. 1 schematically illustrates a display panel according to a first embodiment.

FIG. 2 schematically illustrates the active-matrix substrate of the first embodiment.

FIG. 3A is an enlarged schematic view of a portion of the active-matrix substrate of FIG. 2.

FIG. 3B illustrates an equivalent circuit corresponding to one pixel of FIG. 3A.

FIG. 4 is an enlarged plan view of one pixel of FIG. 3A.

FIG. 5 is a cross-sectional view taken on line A-A′ of FIG. 4.

FIG. 6 is a cross-sectional view of an S-G contact of FIG. 3A, taken on line B-B′.

FIG. 7 is a cross-sectional view of a G-COM contact of FIG. 3A, taken on line C-C′.

FIG. 8 is a cross-sectional view of an S-COM contact of FIG. 3A, taken on line D-D′.

FIG. 9A illustrates a step of a process of fabricating a TFT-PIX contact of the first embodiment.

FIG. 9B illustrates a step of the process of fabricating a TFT-PIX contact of the first embodiment.

FIG. 9C illustrates a step of the process of fabricating a TFT-PIX contact of the first embodiment.

FIG. 9D illustrates a step of the process of fabricating a TFT-PIX contact of the first embodiment.

FIG. 9E illustrates a step of the process of fabricating a TFT-PIX contact of the first embodiment.

FIG. 9F illustrates a step of the process of fabricating a TFT-PIX contact of the first embodiment.

FIG. 9G illustrates a step of the process of fabricating a TFT-PIX contact of the first embodiment.

FIG. 9H illustrates a step of the process of fabricating a TFT-PIX contact of the first embodiment.

FIG. 9I illustrates a step of the process of fabricating a TFT-PIX contact of the first embodiment.

FIG. 10A illustrates a step of another process of fabricating a TFT-PIX contact.

FIG. 10B illustrates a step of the other process of fabricating a TFT-PIX contact.

FIG. 10C illustrates a step of the other process of fabricating a TFT-PIX contact.

FIG. 10D illustrates a step of the other process of fabricating a TFT-PIX contact.

FIG. 10E illustrates a step of the other process of fabricating a TFT-PIX contact.

FIG. 10F illustrates a step of the other process of fabricating a TFT-PIX contact.

FIG. 10G illustrates a step of the other process of fabricating a TFT-PIX contact.

FIG. 10H illustrates a step of the other process of fabricating a TFT-PIX contact.

FIG. 11 illustrates a cross-section of an S-G contact according to a second embodiment.

FIG. 12 illustrates a cross-section of an S-G contact according to a third embodiment.

### EMBODIMENTS FOR CARRYING OUT THE INVENTION

A semiconductor apparatus according to an embodiment of the present invention is a semiconductor apparatus including: a substrate; a plurality of gate lines located on the substrate; a gate insulating film covering the gate lines; a semiconductor layer having portions that overlie the gate lines, with the gate insulating film positioned in between; a plurality of source lines located on the gate insulating film and each covering portions of the semiconductor layer to cross the gate lines; a plurality of drain lines located on the gate insulating film and each covering a portion of the semiconductor layer so as to be spaced apart from one of the source lines across a portion of the semiconductor layer and overlie one of the gate lines; thin film transistors each including a channel region located over a portion of the semiconductor layer between a source line and a drain line; a drain connecting film made of a portion of a metal film for electrically connecting to a drain line via a first contact hole that extends through a first interlayer insulating film and a planarizing film, the first interlayer insulating film covering the source lines and drain lines and the channel regions, the planarizing film covering the first interlayer insulating film; common electrode auxiliary wiring made of a portion of the metal film, including a common electrode auxiliary line overlying at least one of the source lines and a common electrode auxiliary line provided for at least one of the gate lines so as to be located close to this gate line and extend generally parallel thereto; a common electrode overlying at least a part of the common electrode auxiliary line and electrically connected with the common electrode auxiliary line; and a pixel electrode electrically connected with the drain connecting film in a second contact hole, the second contact hole being formed in a second interlayer insulating film that contacts the drain connecting film and being located inside the first contact hole, wherein the metal film is constructed such that a metal having a higher standard electrode potential than the pixel electrode or a metal having a standard electrode potential that differs from that of the pixel electrode by an amount in a predetermined range is included so as to contact the pixel electrode, and the common electrode auxiliary line supplies the common electrode with a potential that depends on an input signal (first arrangement). In the first arrangement, a pixel electrode is electrically connected with a drain line via a drain connecting film made of a metal film that can reduce electric corrosion in ITO, allowing for the use of an aluminum-based metal line, which has a low resistance, as a drain line. Further, the drain connecting film and common electrode auxiliary line are formed from the same metal film, i.e. in the same layer. This makes it possible to form a drain connecting film in the step of forming a common electrode auxiliary line, and thus the number of manufacturing steps is not increased. Furthermore, since a potential can be supplied to the common electrode via the common electrode auxiliary lines, the potential of the common electrode can be stabilized.

In a second arrangement, starting from the first arrangement, the substrate may include first terminals for each providing a gate signal to a gate line, second terminals for each providing a source signal to a source line, and third and fourth terminals for providing a potential to the common electrode, and the first, second, third and fourth terminals may be made from a conductive film used to form the gate lines and formed in the same layer, the semiconductor apparatus further including: a first contact part electrically connecting one of the source lines with the third terminal and electrically connecting the other ones of the source lines with the second terminals; a second contact part, wherein one of the gate lines is electrically connected with the fourth terminal and the other ones of the gate lines are electrically connected with the first terminals, the second contact part electrically connecting the one of the gate lines with the common electrode auxiliary line that overlies the other one of the source lines; and a third contact part electrically connecting the one of the source lines with the common electrode auxiliary line that extends generally parallel to a gate line.

In a third arrangement, starting from the second arrangement, in the first contact part, the one of the source lines may be electrically connected with the third terminal, and the other ones of the source lines may be electrically connected with the second terminals, via portions of the metal film in the same layer as the common electrode auxiliary line and the drain connecting film, in the second contact part, the one of the gate lines may be connected with the common electrode auxiliary lines that overlie the other ones of the source lines via portions of the metal film in the same layer as the common electrode auxiliary lines and the drain connecting films, and in the third contact part, the one of the source lines may be connected with the common electrode auxiliary lines extending generally parallel to gate lines via portions of the metal film in the same layer as the common electrode auxiliary lines and the drain connecting films. In the third arrangement, the step of forming common electrode auxiliary lines and drain connecting films connects the common electrode auxiliary lines with the gate lines or source lines, and thus the number of manufacturing steps is not increased.

In a fourth arrangement, starting from the second arrangement, in the first contact part, the one of the source lines may contact the third terminal, and the other ones of the source lines may contact the second terminals, in contact holes in the gate insulating film located over the third terminal and second terminals, in the second contact part, the one of the gate lines may be connected with the common electrode auxiliary lines that overlie the other ones of the source lines via portions of the metal film in the same layer as the common electrode auxiliary lines and the drain connecting films, and, in the third contact part, the one of the source lines may be connected with the common electrode auxiliary lines extending generally parallel to gate lines via portions of the metal film in the same layer as the common electrode auxiliary lines and the drain connecting films. In the fourth arrangement, a gate line directly contacts a source line in a first contact, thereby reducing the area of each contact compared with the third arrangement.

In a fifth arrangement, starting from one of the first to fourth arrangements, the semiconductor layer may include an oxide semiconductor, the common electrode and the pixel electrode may be made from a transparent conductive film, and the source lines and the drain lines may include aluminum or a metal compound containing aluminum.

In a sixth arrangement, starting from the fifth arrangement, the oxide semiconductor may be made of indium, gallium, zinc and oxygen.

A display panel according to an embodiment of the present invention includes: an active-matrix substrate including the semiconductor apparatus of one of the first to sixth arrangements; a counter-substrate provided with color filters; and a liquid crystal layer retained between the active-matrix substrate and the counter-substrate (seventh arrangement).

A method of manufacturing a semiconductor apparatus according to an embodiment of the present invention is a method of manufacturing a semiconductor apparatus including a thin-film transistor, including: (A) forming a thin-film transistor on a substrate, in which a gate layer including a gate line and a gate electrode, a gate insulating film covering the gate layer, and a semiconductor layer covering a portion of the gate insulating film are formed, and a source layer is formed on top of the semiconductor layer to form a source line including a source electrode and a drain line including a drain electrode; (B) forming a first interlayer insulating film covering the source layer and a planarizing film covering the first interlayer insulating film; (C) etching the first interlayer insulating film using the planarizing film as a mask to form a first contact hole, the first contact hole exposing a portion of the drain electrode; (D) forming a metal film on the planarizing film to form a drain connecting film that contacts the drain line in the first contact hole and form a common electrode auxiliary line that overlies a part of the source line; (E) forming a common electrode that covers the common electrode auxiliary line and stretches outside an area where the drain connecting film is present; (F) forming a second interlayer insulating film on top of the common electrode and the drain connecting film and etching the second interlayer insulating film to form a second contact hole inside the first contact hole, the second contact hole exposing a portion of the drain connecting film; and (G) forming on the second interlayer insulating film a pixel electrode that contacts the drain connecting film in the second contact hole, wherein the drain connecting film and the common electrode auxiliary line are constructed such that a metal having a higher standard electrode potential than the pixel electrode or a metal having a standard electrode potential that differs from that of the pixel electrode by an amount in a predetermined range is include so as to contact the pixel electrode (eighth arrangement).

Now, embodiments of the present invention will be described in detail with reference to the drawings. In the drawings, the same or corresponding parts are designated by the same characters, and their description will not be repeated.

### First Embodiment

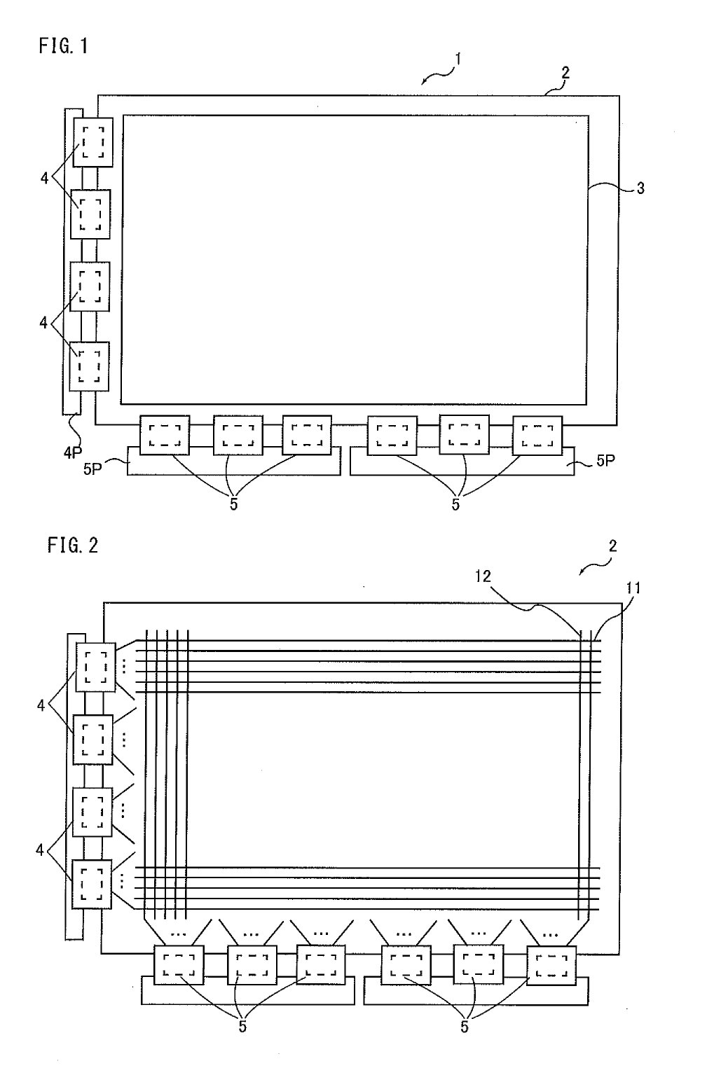

FIG. 1 schematically illustrates a display panel of a liquid crystal display device including a semiconductor apparatus according to the present embodiment. The display panel 1 includes an active-matrix substrate 2, a counter-substrate 3, and a liquid crystal layer (not shown) retained between these substrates. The counter-substrate 3 of FIG. 1 has a color filter substrate (not shown) provided thereon. The display panel 1 is illuminated by a backlight (not shown) provided on the backside of the active-matrix substrate 2. As shown in FIG. 1, the active-matrix substrate 2 has gate drivers 4 and source drivers 5 provided thereon. Based on data signals and scan signals supplied by the source drivers 4 and gate drivers 5 in response to external input signals, the display panel 1 drives liquid crystal in the liquid crystal layer to display images in the display region.

The gate drivers 4 and source drivers 5 are fabricated by tape automated bonding (TAB), for example, where semiconductor chips for the gate drivers 4 and source drivers 5 are mounted on films of polyimide or the like. The gate drivers 4 and source drivers 5 are electrically connected with the active-matrix substrate 2 and electrically connected with their associated print circuit boards 4P and 5P. The gate drivers 4 and source drivers 5 receive external input signals, such as timing signals or image signals, from a control circuit (not shown) via their associated print circuit boards 4P and 5P.

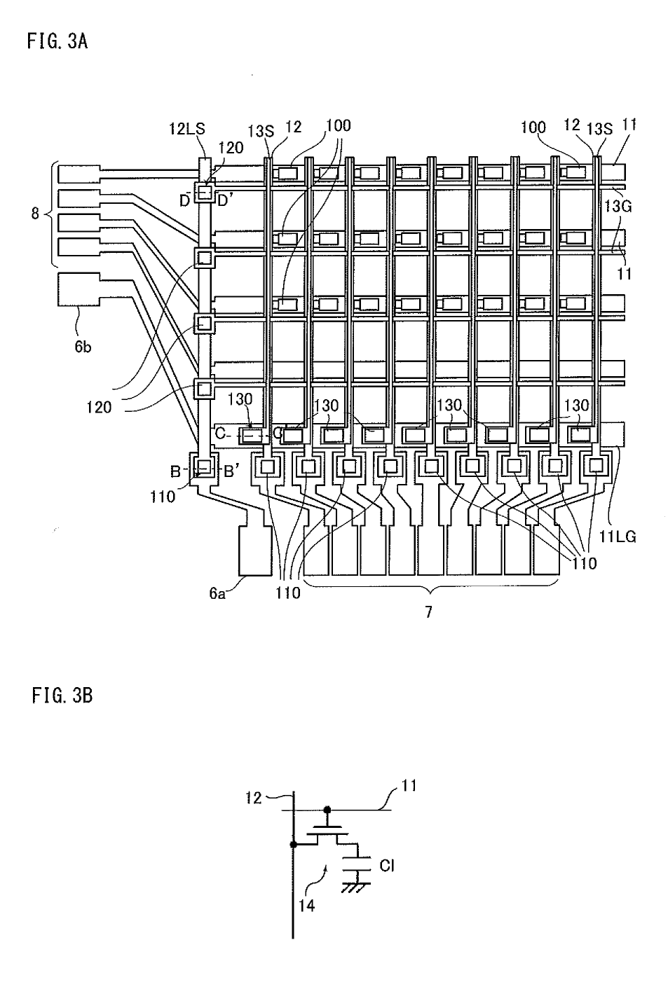

FIG. 2 schematically illustrates the active-matrix substrate 2. FIG. 3A is a schematic enlarged view of a portion of the active-matrix substrate 2. As shown in FIG. 2, above the substrate 20 of the active-matrix substrate 2 are provided multiple gate lines 11 connected with their associated gate drivers 4 and multiple source lines 12 connected with their associated source drivers 5. The gate lines 11 extend parallel to each other in one direction of the substrate 20. The source lines 12 extend parallel to each other to cross the gate lines 11. Each of the regions defined by the gate lines 11 and source lines 12 forms one pixel, and the region formed by all pixels constitutes the display region of the display panel 1.

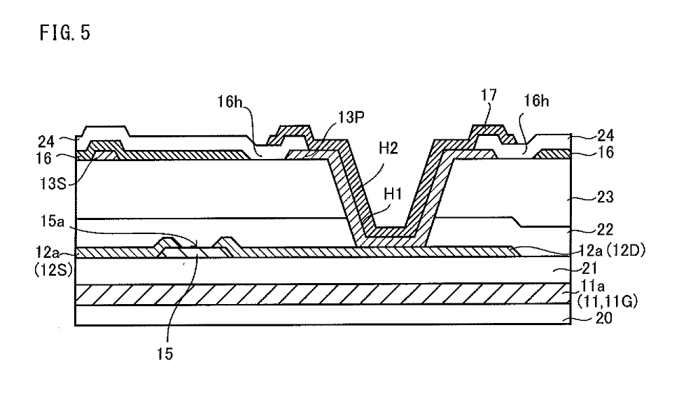

As shown in FIG. 3A, multiple terminals 7 and multiple terminals 8 are provided outside the display region of the active-matrix substrate 2. The terminals 7 supply their respective source lines 12 with source signals provided by the associated source drivers 5. The terminals 8 supply their respective gate lines 11 with gate signals provided by the associated gate drivers 4. In the display region of the active-matrix substrate 2 are provided a common electrode 16 (see FIG. 5), described further below, and pixel electrodes 17 (see FIG. 5). The display panel 1 drives liquid crystal by lateral electric field techniques such as in-plane switching (IPS) and fringe field switching (FFS). Further, terminals 6 (6a, 6b), a line 12LS and a line 11LG are provided on the active-matrix substrate 2. The terminals 6 supply potentials intended for the common electrode 16. The line 12LS is connected with the terminal 6a, and the line 11LG is connected with the terminal 6b.

The terminals 6, 7 and 8 and the line 11LG are formed from the same conductive film as the gate lines 11, i.e. in the same layer as the gate lines 11. The line 12LS is formed from the same conductive film as the source lines 12, i.e. in the same layer as the source lines 12. The terminal 6a is connected with the line 12LS via one or more contact holes. Each terminal 7 is connected with the corresponding source line 12 via one or more contact holes. The terminal 6b and line 11LG are integrally formed and electrically connected with each other, and each terminal 8 and the corresponding gate line 11 are integrally formed and electrically connected with each other. In the present embodiment, the gate lines 11 and line 11LG are examples of the gate lines, and the source lines 12 and line 12LS are examples of the source lines.

FIG. 3B illustrates an equivalent circuit corresponding to one pixel of FIG. 3A. As shown in FIG. 3B, a thin film transistor (TFT) 14 is provided close to the intersection of a source line 12 and a gate line 11, where a capacitor CI is formed by the corresponding pixel electrode 17 and the common electrode 16. In each pixel region, the TFT 14 is electrically connected with the pixel electrode 17 via a contact hole.

FIG. 3A further shows auxiliary lines 13S and 13G provided on the active-matrix substrate 2. The auxiliary lines 13S and 13G supply the common electrode 16 with potentials provided by the terminals 6. The auxiliary lines 13S overlie their respective source lines 12 and cross the gate lines 11. The auxiliary lines 13G extend generally parallel to the gate lines 11, close to the respective gate lines 11, to overlie parts of the line 12LS. The line 12LS is electrically connected with each auxiliary line 13G via a part of this particular auxiliary line 13G and a contact hole. The line 11LG is electrically connected with each auxiliary line 13S via a part of this particular auxiliary line 13S and a contact hole. The auxiliary lines 13S and 13G of the present embodiment are examples of the common electrode auxiliary line.

Each of the regions 100 shown in FIG. 3A, in which a TFT 14 overlaps a pixel electrode (not shown in FIG. 3A), is an area where the TFT 14 is connected with the pixel electrode 17, which will be hereinafter referred to as TFT-PIX contact 100. Each of the regions 110 shown in FIG. 3A, in which the line 12LS or a source line 12 overlaps a terminal (6a, 7), is an area where the line 12LS is connected with the terminal 6a or a source line 12 is connected with a terminal 7 via a contact hole. This will be hereinafter referred to as S-G contact 110. Each of the regions 120, in which an auxiliary line 13G overlaps the line 12LS, is an area where the line 12LS is connected with this particular auxiliary line 13G. This will be hereinafter referred to as S-COM contact 120. Each of the regions 130, in which the line 11LG overlaps an auxiliary line 13S, is an area where the line 11LG is connected with this particular auxiliary line 13S. This region 130 will be hereinafter referred to as G-COM contact 130.

According to the present embodiment, a source signal received by a terminal 7 is transferred to the corresponding source line 12 via the corresponding S-G contact 110. A potential intended for the common electrode 16 received by the terminal 6a is transferred to the auxiliary lines 13G via the S-G contact 110 on the line 12LS and the respective S-COM contacts 120. A potential intended for the common electrode 16 received by the terminal 6b is transferred to the auxiliary lines 13S via the respective G-COM contacts 130.

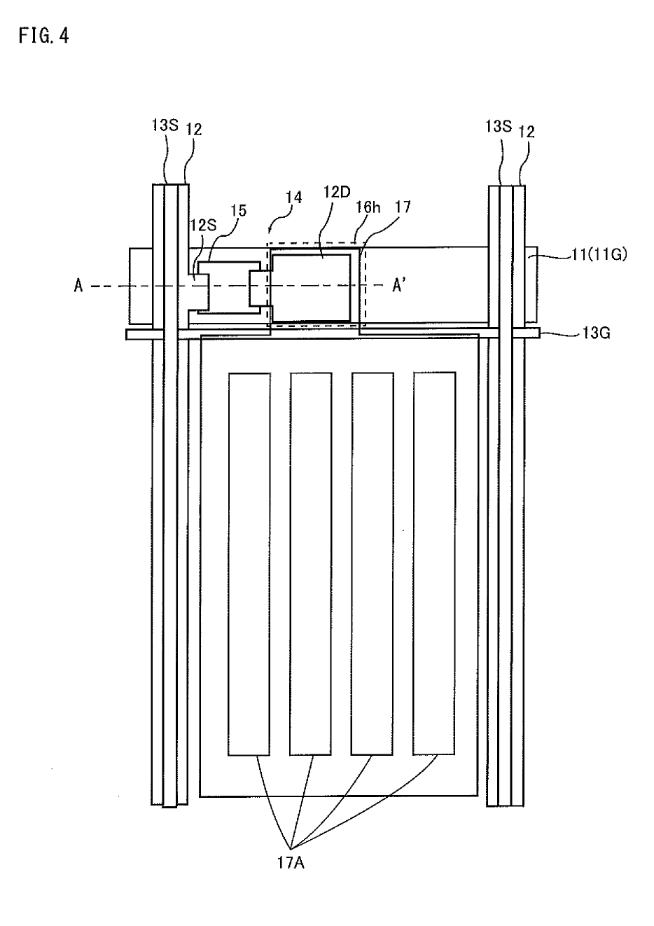

The area of one pixel including a TFT-PIX contact 100 will be described in detail with reference to FIGS. 4 and 5. FIG. 4 is an enlarged plan view of one pixel of FIG. 3A. As shown in FIG. 4, the TFT 14 includes a source electrode 12S, a gate electrode 11G, a drain electrode 12D and a semiconductor element 15. A pixel electrode 17 is provided in each pixel region and includes openings 17A. The pixel electrode 17 is electrically connected with the drain electrode 12D of the TFT 14. Although this figure does not show the common electrode 16 (see FIG. 5), the common electrode 16 is located below the pixel electrodes 17 and covers the area outside the openings 16h of the common electrode 16, suggested by the broken lines. That is, the common electrode 16 covers the entire area of all pixel regions except the regions of the TFT-PIX contacts 100, in each of which a drain electrode 12D is connected with a pixel electrode 17.

FIG. 5 is a cross-sectional view taken on line A-A′ of FIG. 4. As shown in FIG. 5, on top of a transparent and insulating substrate 20 such as glass is provided a gate layer 11a. The gate layer 11a may be made of a metal such as copper (Cu), aluminum (Al), titanium (Ti) and molybdenum (Mo), or an alloy thereof. As the gate layer 11a is formed, gate lines 11 and gate electrodes 11G are formed, each gate line being integral with the associated gate electrodes.

On top of the gate layer 11a is provided a gate insulating film 21 made of a silicon nitride (SiNx) film or silicon oxide (SiO2) film, for example. On top of the gate insulating film 21 is provided a semiconductor element 15. The semiconductor element 15 is formed of amorphous silicon (a-Si), polysilicon (poly-Si) or oxide semiconductor, for example.

On top of the semiconductor element 15 is provided a source layer 12a. The source layer 12a may be made of a single layer film of Al, for example, or a laminated film with an upper layer of Al and a lower layer of Ti. As the source layer 12a is formed, source lines 12 and source electrodes 12S are formed, each source line being integral with the associated source electrodes, and drain electrodes 12D are formed. A source electrode 12S is spaced apart from the corresponding drain electrode 12D across the corresponding semiconductor element 15. A channel region 15a is formed over the semiconductor element 15 between the source electrode 12S and drain electrode 12D. In the present embodiment, the source lines 12 and source electrodes 12S are examples of the source lines, and the drain electrodes 12D are examples of the drain lines.

On top of the source electrode 12S, drain electrode 12D and channel region 15a are provided an interlayer insulating film 22 and a planarizing film 23, on top of each other. A contact hole H1 is formed in portions of the interlayer insulating film 22 and planarizing film 23 that are located above the drain electrode 12D. The interlayer insulating film 22 is made of an inorganic insulating film. The planarizing film 23 is made of an organic insulating film.

On top of the planarizing film 23 is provided an auxiliary line layer 13. The auxiliary line layer 13 may be made of, for example, a metal film that can prevent electric corrosion between itself and pixel electrodes 17. The metal film may be, for example, a laminated film with an uppermost layer, which directly contacts pixel electrodes 17, of Cu, Ti, Mo or the like. The standard electrode potentials of Cu, Ti, Mo and Al, as measured in an aqueous solution at 25° C., if a standard hydrogen electrode is a reference electrode, are as follows: Cu: 0.34 V; Ti: −1.63 V; Mo: −0.02 V; and Al: −1.68 V. The standard electrode potential of ITO, which is used for the pixel electrodes 17, is 0.03 V. That is, the metal film used for the auxiliary line layer 13 is only required to be constructed such that a metal having a higher standard electrode potential than the pixel electrodes 17 or a metal having a standard electrode potential that differs from that of the pixel electrodes 17 by an amount in a predetermined range is included so as to contact the pixel electrodes 17. The difference between the standard electrode potential of the metal and that of the pixel electrodes 17 may be not more than 1.66 V, for example.

As the auxiliary line layer 13 is formed, auxiliary lines 13S and drain connecting films 13P are formed. An auxiliary line 13S is located to overlie the associated source line 12, with the interlayer insulating film 22 and planarizing film 23 positioned in between. A drain connecting film 13P is located in a contact hole H1 so as to contact the associated drain electrode 12D. Although not shown in FIG. 5, auxiliary lines 13G parallel to the gate lines 11 are formed at the same time as the auxiliary lines 13S and drain connecting films 13P.

On top of the planarizing film 23 is formed a common electrode 16. The common electrode 16 has openings 16h so as not to contact the drain connecting films 13P, each of which has portions located on top of the planarizing film 23, and covers the auxiliary lines 13S. On top of the common electrode 16 is provided an interlayer insulating film 24 to cover the common electrode 16 and portions of each drain connecting film 13P, and has contact holes H2 formed therein. A pixel electrode 17 is located in each contact hole H2; the pixel electrodes 17 cover parts of the interlayer insulating film 24. The interlayer insulating film 24 is made of an inorganic insulating film. The common electrode 16 and pixel electrodes 17 are made of a transparent conductive film of ITO, for example.

As shown in FIG. 5, a drain electrode 12D is electrically connected with a pixel electrode 17 via a drain connecting film 13P to form a TFT-PIX contact 100. The auxiliary line layer 13 is made of a material that can prevent electric corrosion between this layer and the pixel electrodes 17. In a TFT-PIX contact 100, the drain connecting film 13P directly contacts the pixel electrode 17. This prevents electric corrosion between the drain connecting film 13P and pixel electrode 17, thereby preventing electric corrosion even when the drain electrode 12D is made of an aluminum-based metal film.

Now, the S-G contacts 110, G-COM contacts 130 and S-COM contacts 120 will be described in detail.

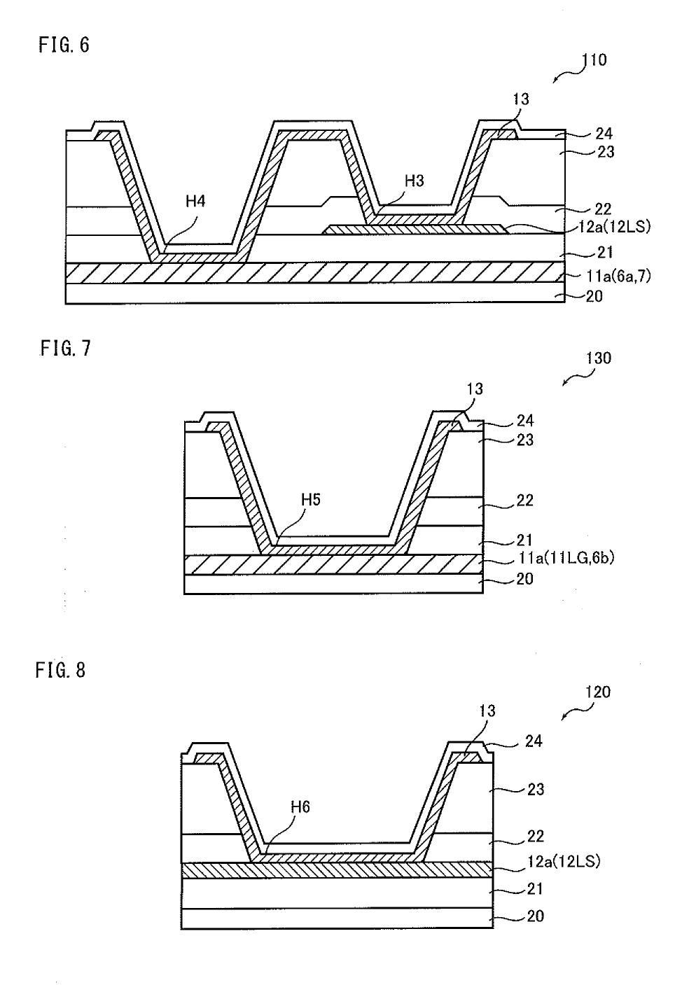

FIG. 6 is a cross-sectional view of an S-G contact 110 of FIG. 3A, taken on line B-B′. As shown in FIG. 6, on top of a substrate 20 is provided a gate layer 11a. As the gate layer 11a is formed, terminals 6a and 7 are formed. Above the gate layer 11a is provided a source layer 12a, with a gate insulating film 21 positioned in between. As the source layer 12a is formed, a line 12LS and the source lines 12 are formed. An interlayer insulating film 22 covers the source layer 12a, and on top of the interlayer insulating film 22 is provided a planarizing film 23.

A contact hole H3 is formed in portions of the planarizing film 23 and interlayer insulating film 22 located above the source layer 12a. A contact hole H4 is formed in portions of the planarizing film 23, interlayer insulating film 22 and gate insulating film 21 that are not overlapped by the source layer 12. On top of the planarizing film 23 is provided an auxiliary line layer 13 portion to connect the contact holes H3 and H4. An interlayer insulating film 24 covers the auxiliary line layer 13.

Thus, in the present embodiment, the line 12LS (in the source layer 12a) is electrically connected with the terminal 6a (in the gate layer 11a) via an auxiliary line layer 13 provided in the associated contact holes H3 and H4. Further, a source line 12 (in the source layer 12a) is electrically connected with a terminal 7 (in the gate layer 11a) via the auxiliary line layer 13. This allows a source signal received by a terminal 7 to be transferred to the corresponding source line 12 via the auxiliary line layer 13 portion.

FIG. 7 is a cross-sectional view of a G-COM contact 130 of FIG. 3A, taken along line C-C′. As shown in FIG. 7, on top of a substrate 20 is provided a gate layer 11a. As the gate layer 11a is formed, a terminal 6b and line 11LG are integrally formed. On top of the gate layer 11a are provided a gate insulating film 21, an interlayer insulating film 22 and a planarizing film 23, formed in this order. A contact hole H5 is formed in the gate insulating film 21, interlayer insulating film 22 and planarizing film 23 to expose a portion of the gate layer 11a. On top of the planarizing film 23 is provided an auxiliary line layer 13. The auxiliary line layer 13 contacts the gate layer 11a in the contact hole H5. An interlayer insulating film 24 covers the auxiliary line layer 13.

Thus, the line 11LG formed integrally with the terminal 6b is electrically connected with the common electrode 16 via an auxiliary line layer 13 formed in the contact hole H5. This allows a potential received by the terminal 6b to be supplied to the common electrode 16 via the auxiliary line layer 13, thereby stabilizing the potential of the common electrode 16.

FIG. 8 is a cross-sectional view of an S-COM contact 120 of FIG. 3A, taken along line D-D′. As shown in FIG. 8, above a substrate 20 is provided a source layer 12a, with a gate insulating film 21 positioned in between. As the source layer 12a is formed, a line 12LS is formed. On top of the source layer 12a are provided an interlayer insulating film 22 and a planarizing film 23, formed in this order. A contact hole H6 is formed in the interlayer insulating film 22 and planarizing film 23. On top of the planarizing film 23 is provided an auxiliary line layer 13. The auxiliary line layer 13 contacts the source layer 12a in the contact hole H6. An interlayer insulating film 24 covers the auxiliary line layer 13.

Thus, the line 12LS (in the source layer 12a) is electrically connected with the common electrode 16 via an auxiliary line layer 13 provided in the contact hole H6. This allows a potential received by the terminal 6a to be transferred to the line 12LS (in the source layer 12a) via an S-G contact 110 shown in FIG. 6 and supplied to the common electrode 16 from the line 12LS (in the source layer 12a) via the auxiliary line layer 13.

(Manufacturing Method)

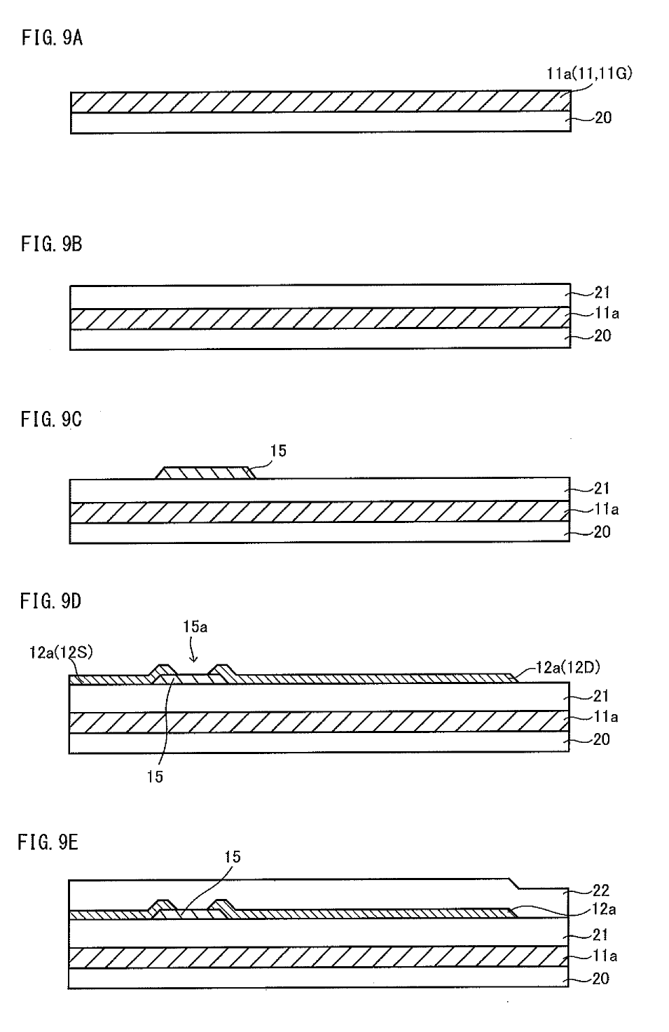

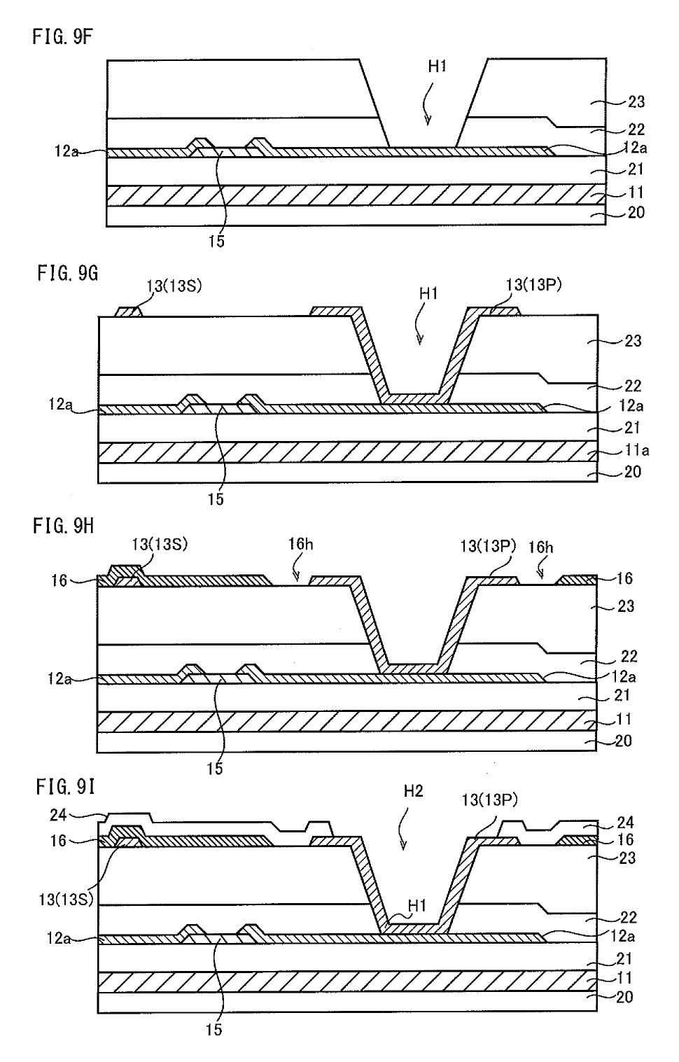

An exemplary method of manufacturing a semiconductor apparatus according to the present embodiment will be described below. FIGS. 9A to 9I, which illustrate steps of a process of forming a TFT-PIX contact 100 shown in FIG. 5, are cross-sectional views taken along line A-A′ of FIG. 4. The present embodiment uses eight masks in steps (1) to (10) described below. The following describes the steps for a TFT-PIX contact 100, together with the formation of an S-G contact 110, S-COM contact 120 and G-COM contact 130.

(1) Formation of Gate Layer 11a

As shown in FIG. 9A, on a substrate 20, a conductive film for a gate layer 11a is formed by sputtering. Then, a resist mask is photolithographically formed to be aligned with an array of positions where TFTs 14 are to be formed, forming a resist pattern. Further, the conductive film is patterned by removing the portions of the film that are not covered with the resist mask by wet etching or dry etching. This is the first masking step. This forms gate electrodes 11G and gate lines 11, each gate line being integral with the associated gate electrodes. Similarly, in the S-G contact 110 and G-COM contact 130, a terminal 6 or 7 and line 11LG are formed on the substrate 20, as shown in FIGS. 6 and 7.

The gate layer 11a may be made of a film containing, for example, a metal such as Cu, Al, Ti and Mo or an alloy thereof or a nitride thereof. The present embodiment uses as an example a laminated film with an upper layer of Cu and a lower layer of Ti. The upper layer has a thickness of not less than 180 nm and not more than 300 nm, for example, and the lower layer has a thickness of not less than 15 nm and not more than 35 nm, for example.

(2) Formation of Gate Insulating Film 21

After the formation of the gate layer 11a, a gate insulating film 21 is formed over the substrate 20 by plasma CVD or sputtering, as shown in FIG. 9B. Also, in the S-G contact 110, G-COM contact 130 and S-COM contact 120, the gate insulating film 21 is formed, as shown in FIGS. 6, 7 and 8. The gate insulating film 21 may be, for example, a silicon nitride film or silicon oxide film or a lamination of such films. The gate insulating film 21 has a thickness of not less than 200 nm and not more than 400 nm, for example.

(3) Formation of Semiconductor Element 15

After the formation of the gate insulating film 21, a semiconductor is formed over the substrate 20 by plasma CVD or sputtering. Then, a resist pattern is photolithographically formed, and wet etching or dry etching occurs. Thus, the semiconductor is patterned to leave insular portions, as shown in FIG. 9C. This is the second masking step. The semiconductor may be, for example, a-Si, poly-Si or an oxide semiconductor such as IGZO or InGaO3 (ZnO)5. The semiconductor elements 15 have a thickness of not less than 30 nm and not more than 100 nm, for example.

(4) Formation of Source Layer 12a

After the formation of the semiconductor elements 15, a conductive film for a source layer 12a is formed over the substrate 20 by sputtering. Then, a resist pattern is photolithographically formed to be aligned with an array of positions where source lines 12 and source electrodes 12S and drain electrodes 12D are to be formed, and the film is etched by wet etching or dry etching or a combination thereof. This is the third masking step.

Thus, on each semiconductor element 15, a source line 12 and a source electrode 12S and drain electrode 12D are formed such that the source electrode 12S is spaced apart from the drain electrode 12D, as shown in FIG. 9D. Similarly, in the S-G contact 110 and S-COM contact 120, a line 12LS is formed on the gate insulating film 21, as shown in FIGS. 6 and 8.

The source layer 12a may be, for example, a metal film containing a metal such as Al, Mo, Cu, Ti, tantalum (Ta) and tungsten (W) or an alloy thereof or a metal nitride thereof. The present embodiment uses a laminated film with an upper layer of Al and a lower layer of Ti. The source layer 12a has a thickness of not less than 180 nm and not more than 300 nm, for example.

(5) Formation of Interlayer Insulating Film 22 and Planarizing Film 23

After the formation of the source layer 12a, an interlayer insulating film 22 is formed over the substrate 20 by plasma CVD or sputtering, as shown in FIG. 9E. After the formation of the interlayer insulating film 22, a planarizing film 23 is formed over the substrate 20, and is photolithographically patterned to form openings (not shown) in the planarizing film 23. This is the fourth masking step. The interlayer insulating film 22 may be, for example, an inorganic insulating film such as a silicon nitride film or silicon oxide film, or a lamination of such films. The planarizing film 23 may be, for example, an organic insulating film such as a positive photosensitive resin film. The interlayer insulating film 22 has a thickness of not less than 200 nm and not more than 300 nm, for example. The planarizing film 23 has a thickness of not less than 2 μm and not more than 3 μm, for example.

Then, the interlayer insulating film 22 is etched by dry etching, where the planarizing film 23 is used as a mask. This forms contact holes H1, as shown in FIG. 9F. Each of them exposes a portion of the surface of the associated drain electrode 12D. Similarly, in the S-G contact 110 and S-COM contact 120, contact holes H3 and H6 for exposing some portions of the source layer 12a are formed at the same time as the contact holes H1 are formed, as shown in FIGS. 6 and 8. Further, in the S-G contact 110 and G-COM contact 130, after the openings are formed in the planarizing film 23, the interlayer insulating film 22 and gate insulating film 21 are etched at the same time, where the planarizing film 23 is used as a mask, thereby forming contact holes H4 and H5, as shown in FIGS. 6 and 7.

(6) Formation of Auxiliary Line Layer 13

After the planarizing film 23 is formed and a portion of the surface of each drain electrode 12D is exposed, a conductive film for an auxiliary line layer 13 is formed over the substrate 20 by sputtering. Then, a resist pattern is photolithographically formed to be aligned with an array of positions where auxiliary lines 13S and 13G are to be formed, and the film is patterned by wet etching or dry etching or a combination thereof. This is the fifth masking step. Thus, as shown in FIG. 9G, drain connecting films 13P are formed in the respective contact holes H1, and auxiliary lines 13S are formed to overlie the respective source lines 12, with the interlayer insulating film 22 and planarizing film 23 positioned in between. Similarly, as shown in FIGS. 6, 7 and 8, in the S-G contact 110, G-COM contact 130 and S-COM contact 120, the auxiliary line layer 13 is formed in the contact holes H3, 4, 5 and 6 at the same time as the drain connecting films 13P and auxiliary lines 13S are formed.

The sub-layer of the auxiliary line layer 13 that is to contact pixel electrodes, i.e. the top surface, is only required to be made of a metal having a higher standard electrode potential than ITO, used for the pixel electrodes 17, or a metal having a standard electrode potential that differs from that of the pixel electrodes 17 by an amount in a predetermined range. For example, the auxiliary line layer 13 may have a top surface made of Cu, Ti or Mo and be a double-laminated film of Cu/Ti or Cu/Mo or a triple laminated film of Mo/Al/Mo or Ti/Al/Ti. The auxiliary line layer 13 has a thickness of not less than 200 nm and not more than 350 nm, for example.

(7) Formation of Common Electrode 16

After the formation of the auxiliary line layer 13, a transparent conductive film is formed over the substrate 20 by sputtering. Then, a resist pattern is photolithographically formed to be aligned with a geometry in which a common electrode 16 is to be formed, and the film is etched by wet etching so as to be patterned. This is the sixth masking step. This forms openings 16h in a common electrode 16, where the film portions outside the openings 16h form the common electrode 16, as shown in FIG. 9H.

The common electrode 16 may be, for example, a transparent conductive film of indium tin oxide (ITO) or indium zinc oxide (IZO). The common electrode 16 has a thickness of not less than 60 nm and not more than 120 nm, for example. After the patterning, the common electrode 16 may be baked to reduce its resistance.

(8) Formation of Interlayer Insulating Film 24

After the formation of the common electrode 16, an interlayer insulating film 24 is formed over the substrate 20, by plasma CVD or sputtering. Then, a resist pattern is photolithographically formed and the film is etched by dry etching to be patterned. This is the seventh masking step. This forms a contact hole H2 inside each contact hole H1 and forms an interlayer insulating film 24 over the common electrode 16, as shown in FIG. 9I. Similarly, in the S-G contact 110, G-COM contact 130 and S-COM contact 120, the interlayer insulating film 24 is formed on top of the auxiliary line layer 13, as shown in FIGS. 6, 7 and 8. The interlayer insulating film 24 may be, for example, an inorganic insulating film such as a silicon nitride film or silicon oxide film or a lamination of such films. The interlayer insulating film 24 has a thickness of not less than 100 nm and not more than 300 nm, for example. In the present embodiment, the contact hole H1 is an example of the first contact hole, and the contact hole H2 is an example of the second contact hole.

(9) Formation of Pixel Electrode 17

After the formation of the interlayer insulating film 24, a transparent conductive film is formed over the substrate 20 by sputtering. Then, a resist pattern is photolithographically formed to be aligned with an array of positions where pixel electrodes 17 are to be formed, and the film is etched by wet etching so as to be patterned. This is the eighth masking step. This forms pixel electrodes 17, each of which overlies parts of the interlayer insulating film 24 and the associated drain connecting film 13P, as shown in FIG. 5. Further, the pixel electrode 17 is electrically connected with the associated drain electrode 12D via the drain connecting film 13P. After the patterning, the pixel electrodes 17 may be baked to reduce its resistance.

The pixel electrodes 17 may be made from a thin oxide film of indium tin oxide (ITO) or indium zinc oxide (IZO), for example. The pixel electrodes 17 have a thickness of not less than 60 nm and not more than 120 nm, for example. The drain connecting films 13P are made from a metal film that can prevent electric corrosion between itself and the pixel electrodes 17. Since a pixel electrode 17 does not directly contact the associated drain electrode 12D, electric corrosion may be prevented between the pixel electrode 17 and the drain electrode 12D when the pixel electrode 17 is formed.

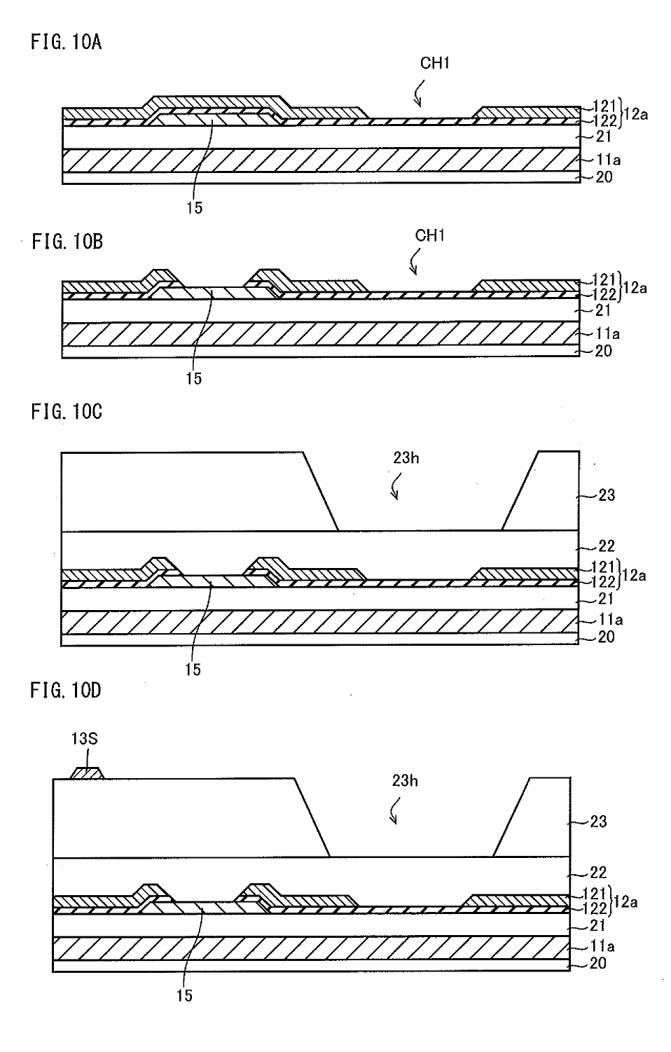

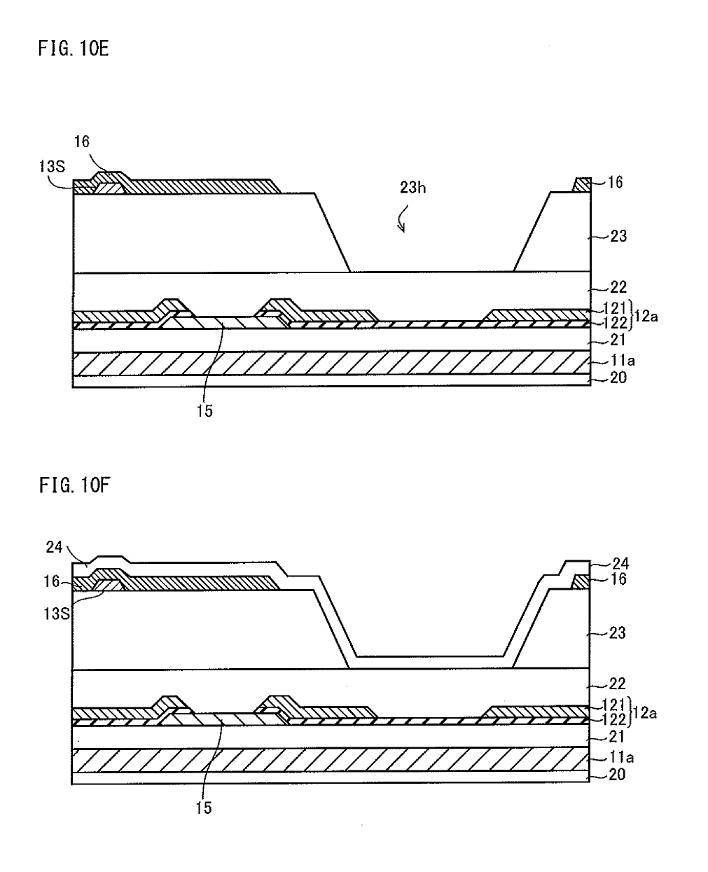

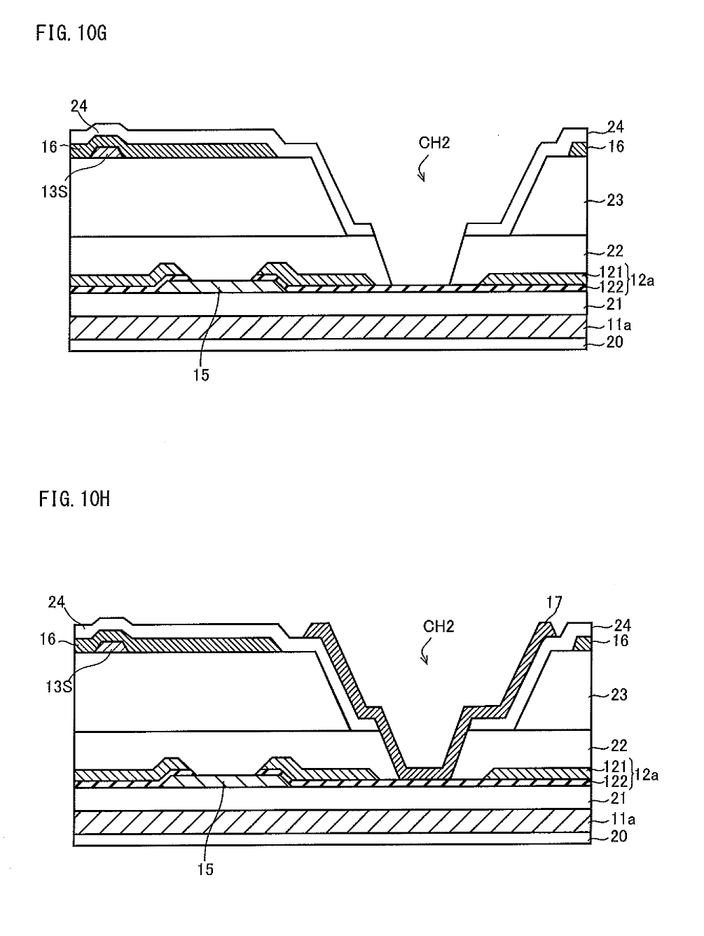

As described above, the present embodiment uses eight masks in the first to eighth masking steps. The present embodiment forms drain connecting films 13P before forming pixel electrodes 17 in order to prevent electric corrosion between the pixel electrodes 17 and the drain electrodes 12D. A different arrangement that prevents electric corrosion in pixel electrodes 17 will be discussed, where drain connecting films 13P are not provided. In the following implementation, only auxiliary lines 13S are formed to stabilize the potential of the common electrode 16. FIGS. 10A to 10H illustrate steps of a process for manufacturing such an arrangement.

After steps (1) to (3) described above, semiconductor elements 15 are present on the gate insulating film 21, as shown in FIG. 10A. Then, a source layer 12a with an upper layer 121 of aluminum and a lower layer 122 of titanium is formed to cover the semiconductor elements 15 and is photolithographically patterned. Then, only the upper layer 121 of the source layer 12a is partially etched away to expose some portions of the lower layer 122. This forms contact holes CH1 in the source layer 12a, as shown in FIG. 10B (step (4′)). Subsequently, as with step (4) described above, photolithographic patterning and etching occur in alignment with an array of positions where source lines 12, source electrodes 12S and drain electrodes 12D are to be formed. This forms a source electrode 12S and a drain electrode 12D over each semiconductor element 15, as shown in FIG. 10B.

Then, according to step (5) of the above embodiment, an interlayer insulating film 22 is formed, and a planarizing film 23 is formed and photolithographically patterned to form openings 23h in the planarizing film 23, as shown in FIG. 10C.

Subsequently, as with step (6) of the above embodiment, an auxiliary line layer 13 is formed, and photolithographic patterning and etching occur in alignment with the source lines 12. This forms auxiliary lines 13S, as shown in FIG. 10D. Then, as with step (7) of the above embodiment, photolithographic patterning and etching occur in alignment with a geometry in which a common electrode 16 is to be formed. This forms a common electrode 16, as shown in FIG. 10E.

After the common electrode 16 is formed, as with step (8) described above, an interlayer insulating film 24 is formed on top of the common electrode 16, as shown in FIG. 10F. Then, photolithographic patterning occurs and the interlayer insulating film 24 and interlayer insulating film 22 are etched simultaneously. This forms contact holes CH2, as shown in FIG. 10G, exposing some portions of the lower layer 122 of the source layer 12a. Subsequently, as with step (9) described above, photolithographic patterning occurs. This forms pixel electrodes 17 on top of the interlayer insulating film 24 to cover the associated contact holes CH2, as shown in FIG. 10H.

As shown in FIG. 10H, in implementations where drain connecting films 13P are not formed, some portions of the upper layer 121 of the source layer 12a are removed to allow the lower layer 122 to directly contact the pixel electrodes 17. That is, the aluminum, which may cause electric corrosion between itself and the pixel electrodes 17, does not contact the pixel electrodes 17; instead, the titanium directly contacts the pixel electrodes 17. As such, a pixel electrode 17 is electrically connected with the associated drain electrode 12D (in the source layer 12a) while preventing electric corrosion between the pixel electrode 17 and drain electrode 12D.

In the manufacturing process illustrated in FIGS. 10A to 10H, step (4′) is required in addition to steps (1) to (9). Step (4′) forms a contact hole CH1 for exposing some portions of the lower layer 122 of the source layer 12a. Thus, the process of FIGS. 10A to 10H requires an additional mask in step (4′). As a result, one more mask is required than in the embodiment above. In the present embodiment, a drain connecting film 13P is formed in each TFT-PIX contact 100 at the same time as the auxiliary lines 13S. Thus, a pixel electrode 17 is formed on the drain connecting film 13P and is connected with the associated drain electrode 12D via the drain connecting film 13P. This eliminates the necessity to form contact holes CH1 as in FIG. 10A, thereby reducing the number of masks compared with the manufacturing process of FIGS. 10A to 10H.

### Second Embodiment

The first embodiment above describes an implementation where an S-G contact 110 of FIG. 6 is constructed such that the gate layer 11a is connected with the source layer 12a via the auxiliary line layer 13; alternatively, an S-G contact may be constructed in the following manner.

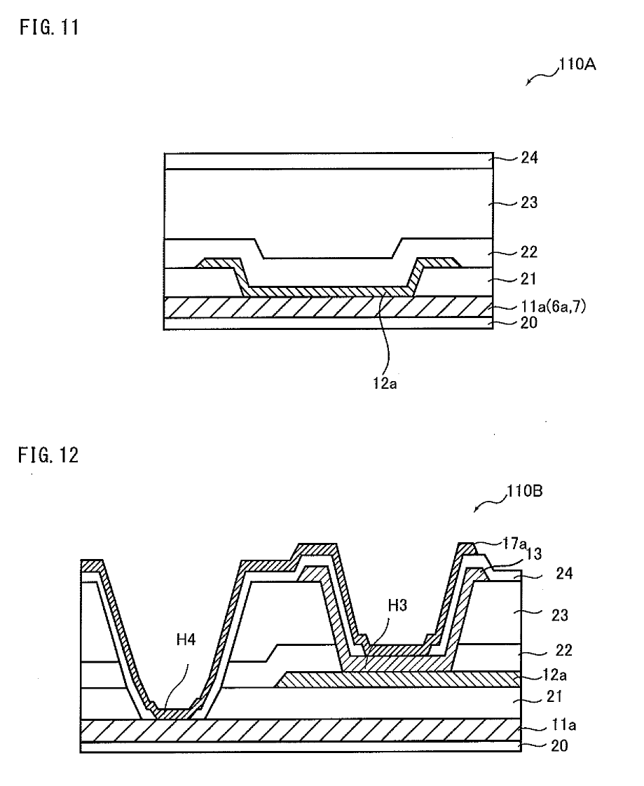

FIG. 11 illustrates a cross-section of an S-G contact 110A according to the present embodiment. In the present embodiment, after the gate insulating film 21 is formed on the gate layer 11a, photolithographic patterning occurs and the gate insulating film 21 is subjected to dry etching, as shown in FIG. 11. This forms openings in the gate insulating film 21. Then, a source layer 12a is formed in these openings according to step (4) of the first embodiment. After the source layer 12a is formed, an interlayer insulating film 22, planarizing film 23 and interlayer insulating film 24 are formed in this order according to steps (5) and (8) of the first embodiment.

In the first embodiment illustrated in FIG. 6, the auxiliary line layer 13 that connects the gate layer 11a with the source layer 12a is formed at the same time as the drain connecting films 13P. This eliminates the necessity to use a mask for connecting the gate layer 11a with the source layer 12a. On the other hand, the arrangement of the present embodiment, shown in FIG. 11, requires a mask for forming an opening that allows the gate layer 11a to directly contact the source layer 12a before the source layer 12a is formed. In exchange, the implementation of FIG. 11 allows the gate layer 11a to be directly connected with the source layer 12a. This reduces the surface area of each S-G contact 110 compared with the first embodiment such that the width of the picture frame of the display panel may be reduced.

### Third Embodiment

The first embodiment above describes an implementation where an S-G contact 110 of FIG. 6 is constructed such that the gate layer 11a is connected with the source layer 12a via the auxiliary line layer 13; alternatively, an S-G contact may be constructed in the following manner.

FIG. 12 illustrates a cross-section of an S-G contact 110B according to the present embodiment. As shown in FIG. 12, in the present embodiment, contact holes H3 and H4 are formed according to step (5) of the first embodiment above and then an auxiliary line layer 13 is formed according to step (6), but only in the contact hole H3. Subsequently, as with step (8), an interlayer insulating film 24 is formed to cover the auxiliary line layer 13, contact holes H4 and planarizing film 23.

After the interlayer insulating film 24 is formed, photolithographic patterning occurs and the portions of only the interlayer insulating film 24 that are located in the contact holes H3 and H4 are subjected to dry etching. This exposes some portions of the gate layer 11a and auxiliary line layer 13. Then, as with step (9), at the same time as pixel electrodes 17 are formed, a pixel electrode layer 17a is formed to cover the interlayer insulating film 24. The pixel electrode layer 17a is made of the conductive film from which the pixel electrodes 17 are made.

Thus, the source layer 12a and pixel electrode layer 17a are stacked, with the auxiliary line layer 13 positioned in between. Since the auxiliary line layer 13 is made of a metal that can prevent electric corrosion between itself and the pixel electrodes 17, no electric corrosion occurs when the pixel electrode layer 17a is formed. Accordingly, a low-resistant aluminum-based metal film may be used for the source layer 12a. Further, the gate layer 11a is electrically connected with the source layer 12a via the pixel electrode layer 17a. In the present embodiment, the gate layer 11a is constructed such that the top surface, which directly contacts the pixel electrode layer 17a, is made of a material that can prevent electric corrosion between itself and ITO, similar to the auxiliary line layer 13. A potential for the common electrode 16 received by the terminal 6a is transferred to the source layer 12a via the pixel electrode layer 17a, and is supplied to the common electrode 16 via the S-COM contacts 120.

While embodiments of the present invention have been described, the above embodiments are merely illustrative examples that may be used to carry out the present invention. Accordingly, the present invention is not limited to the above embodiments and may be carried out with modifications to the above embodiments without departing from the spirit of the invention. Variations of the present invention will be described below.

(1) The first to third embodiments above illustrate implementations where the display panel 1 is a liquid crystal panel; alternatively, the display panel may be an organic electroluminescent panel.

(2) The first to third embodiments above illustrate implementations where the auxiliary lines 13G are located close to the respective gate lines 11 and extend parallel to the gate lines 11; alternatively, the auxiliary lines 13G may be constructed in the following manner: An auxiliary line 13G may be located above the corresponding gate line 11 so as not to overlie the corresponding TFT-PIX contacts 100.

(3) The first to third embodiments above illustrate implementations where the auxiliary lines 13S and 13G are allocated to all the pixels; alternatively, the auxiliary lines may be constructed in the following manner: For example, specified gate lines 11 may have auxiliary lines 13G located close thereto, and specified source lines 12 may have auxiliary lines 13S located to overlie them. In short, only some gate lines 11 are required to have auxiliary lines 13G located close thereto, and only some source lines 12 are required to have auxiliary lines 13S overlying them so as to allow a potential to be supplied to the common electrode 16 through some of the pixel regions.

### INDUSTRIAL APPLICABILITY

The present invention is industrially useful in a display panel such as a liquid crystal panel or organic EL panel for use in a display device.

1-8. (canceled)

9. A semiconductor apparatus comprising:
a substrate;
a plurality of gate lines located on the substrate;
a gate insulating film covering the gate lines;
a semiconductor layer having portions that overlie the gate lines, with the gate insulating film positioned in between;
a plurality of source lines located on the gate insulating film and each covering portions of the semiconductor layer to cross the gate lines;
a plurality of drain lines located on the gate insulating film and each covering a portion of the semiconductor layer so as to be spaced apart from one of the source lines across a portion of the semiconductor layer and overlie one of the gate lines;
thin film transistors each including a channel region located over a portion of the semiconductor layer between a source line and a drain line;
a drain connecting film made of a portion of a metal film for electrically connecting to a drain line via a first contact hole that extends through a first interlayer insulating film and a planarizing film, the first interlayer insulating film covering the source lines and drain lines and the channel regions, the planarizing film covering the first interlayer insulating film;
common electrode auxiliary wiring made of a portion of the metal film, including a common electrode auxiliary line overlying at least one of the source lines and a common electrode auxiliary line provided for at least one of the gate lines so as to be located close to this gate line and extend generally parallel thereto;
a common electrode overlying at least a part of the common electrode auxiliary line and electrically connected with the common electrode auxiliary line; and
a pixel electrode electrically connected with the drain connecting film in a second contact hole, the second contact hole being formed in a second interlayer insulating film that contacts the drain connecting film and being located inside the first contact hole,
wherein the metal film is constructed such that a metal having a higher standard electrode potential than the pixel electrode or a metal having a standard electrode potential that differs from that of the pixel electrode by an amount in a predetermined range is included so as to contact the pixel electrode, and
the common electrode auxiliary line supplies the common electrode with a potential that depends on an input signal.

10. The semiconductor apparatus according to claim 9, wherein the substrate includes first terminals for each providing a gate signal to a gate line, second terminals for each providing a source signal to a source line, and third and fourth terminals for providing a potential to the common electrode, and
the first, second, third and fourth terminals are made from a conductive film used to form the gate lines and formed in the same layer,
the semiconductor apparatus further comprising:
a first contact part electrically connecting one of the source lines with the third terminal and electrically connecting the other ones of the source lines with the second terminals;
a second contact part, wherein one of the gate lines is electrically connected with the fourth terminal and the other ones of the gate lines are electrically connected with the first terminals, the second contact part electrically connecting the one of the gate lines with the common electrode auxiliary line that overlies the other one of the source lines; and
a third contact part electrically connecting the one of the source lines with the common electrode auxiliary line that extends generally parallel to a gate line.

11. The semiconductor apparatus according to claim 10, wherein, in the first contact part, the one of the source lines is electrically connected with the third terminal, and the other ones of the source lines are electrically connected with the second terminals, via portions of the metal film in the same layer as the common electrode auxiliary line and the drain connecting film,
in the second contact part, the one of the gate lines is connected with the common electrode auxiliary lines that overlie the other ones of the source lines via portions of the metal film in the same layer as the common electrode auxiliary lines and the drain connecting films, and
in the third contact part, the one of the source lines is connected with the common electrode auxiliary lines extending generally parallel to gate lines via portions of the metal film in the same layer as the common electrode auxiliary lines and the drain connecting films.

12. The semiconductor apparatus according to claim 10, wherein, in the first contact part, the one of the source lines contacts the third terminal, and the other ones of the source lines contact the second terminals, in contact holes in the gate insulating film located over the third terminal and second terminals,
in the second contact part, the one of the gate lines is connected with the common electrode auxiliary lines that overlie the other ones of the source lines via portions of the metal film in the same layer as the common electrode auxiliary lines and the drain connecting films, and,
in the third contact part, the one of the source lines is connected with the common electrode auxiliary lines extending generally parallel to gate lines via portions of the metal film in the same layer as the common electrode auxiliary lines and the drain connecting films.

13. The semiconductor apparatus according to claim 9, wherein:
the semiconductor layer includes an oxide semiconductor,
the common electrode and the pixel electrode are made from a transparent conductive film, and
the source lines and the drain lines include aluminum or a metal compound containing aluminum.

14. The semiconductor apparatus according to claim 13, wherein the oxide semiconductor is made of indium, gallium, zinc and oxygen.

15. A display panel comprising:
an active-matrix substrate including the semiconductor apparatus according to claim 9;
a counter-substrate provided with color filters; and
a liquid crystal layer retained between the active-matrix substrate and the counter-substrate.

16. A method of manufacturing a semiconductor apparatus including a thin-film transistor, comprising:
(A) forming a thin-film transistor on a substrate, in which a gate layer including a gate line and a gate electrode, a gate insulating film covering the gate layer, and a semiconductor layer covering a portion of the gate insulating film are formed, and a source layer is formed on top of the semiconductor layer to form a source line including a source electrode and a drain line including a drain electrode;
(B) forming a first interlayer insulating film covering the source layer and a planarizing film covering the first interlayer insulating film;
(C) etching the first interlayer insulating film using the planarizing film as a mask to form a first contact hole, the first contact hole exposing a portion of the drain electrode;
(D) forming a metal film on the planarizing film to form a drain connecting film that contacts the drain line in the first contact hole and form a common electrode auxiliary line that overlies a part of the source line;
(E) forming a common electrode that covers the common electrode auxiliary line and stretches outside an area where the drain connecting film is present;
(F) forming a second interlayer insulating film on top of the common electrode and the drain connecting film and etching the second interlayer insulating film to form a second contact hole inside the first contact hole, the second contact hole exposing a portion of the drain connecting film; and
(G) forming on the second interlayer insulating film a pixel electrode that contacts the drain connecting film in the second contact hole,
wherein the drain connecting film and the common electrode auxiliary line are constructed such that a metal having a higher standard electrode potential than the pixel electrode or a metal having a standard electrode potential that differs from that of the pixel electrode by an amount in a predetermined range is included so as to contact the pixel electrode.

17. The method of manufacturing a semiconductor apparatus including a thin-film transistor according to claim 16, wherein:
the semiconductor layer includes an oxide semiconductor.

18. The method of manufacturing a semiconductor apparatus including a thin-film transistor according to claim 17, wherein:
the oxide semiconductor is made of indium, gallium, zinc and oxygen.
